(19) United States
(12) Patent Application Publication
(10) Pub. No.: US 2024/0096589 A1
(43) Pub. Date: Mar. 21, 2024

(54) SEMICONDUCTOR CHARGED PARTICLE DETECTOR FOR MICROSCOPY

(71) Applicant: ASML Netherlands B.V., Veldhoven (NL)

(72) Inventors: Stoyan NIHTIANOV, Eindhoven (NL); Kenichi KANAI, Palo Alto, CA (US); Padmakumar RAMACHANDRA RAO, Veldhoven (NL)

(73) Assignee: ASML Netherlands B.V., Veldhoven (NL)

(21) Appl. No.: 18/038,206

(22) PCT Filed: Oct. 26, 2021
(86) PCT No.: PCT/EP2021/079725

§ 371 Date: May 22, 2023

Related U.S. Application Data
(60) Provisional application No. 63/117,411, filed on Nov. 23, 2020.

(51) Int. Cl. H01J 37/244

(52) U.S. Cl. CPC H01J 37/244; H01J 2237/2441; H01J 2237/2446; H01J 2237/24495

(57) ABSTRACT

A detector may be provided for a charged particle apparatus comprising:
a sensing element including a diode; and
a circuit configured to detect an electron event caused by an electron impacting the sensing element,
wherein the circuit comprises a voltage monitoring device and a reset device,
wherein the reset device is configured to regularly reset the diode by setting a voltage across the diode to a predetermined value,
   and wherein the voltage monitoring device is connected to the diode to monitor a voltage across the diode in between resets.

### CROSS-REFERENCE TO RELATED APPLICATIONS

This application claims priority of U.S. application 63/117,411 which was filed on 23 Nov. 2020, and which is incorporated herein in its entirety by reference.

### FIELD

The description herein relates to charged particle detection, and more particularly, to systems and methods that may be applicable to charged particle beam detection.

### BACKGROUND

Detectors may be used for sensing physically observable phenomena. For example, charged particle beam tools, such as electron microscopes, may comprise detectors that receive charged particles projected from a sample and that output a detection signal. Detection signals can be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Dedicated inspection tools may be provided for this purpose.

In some applications in the field of inspection, for example microscopy using a scanning electron microscope (SEM), an electron beam may be scanned across a sample to derive information from backscattered or secondary electrons generated from the sample. In a related art, electron detection systems in SEM tools may include a detector configured to detect electrons coming from the sample. Existing detectors in SEM tools may detect only the intensity of the beam. In some detection methods, a large area semiconductor detector or a group of small area semiconductor detectors having an area equal to, smaller, or larger than the area of the beam spot may be used. Current induced by the incoming electron beam may be generated within the detector and then amplified by an amplifier following the detector. Performance of the detection may be limited due to the amplifier which may have a relatively large power consumption resulting for instance in a poor signal-to-noise ratio (SNR), particularly when beam current reduces to, for example, pico-ampere ranges.

With continuing miniaturization of semiconductor devices, inspection systems may use lower and lower electron beam currents. As beam current decreases, maintaining SNR becomes even more difficult. For example, when probe current decreases to 200 pA or below, SNR may drop off dramatically. Poor SNR may require taking measures such as image averaging or extending the integration time of signal corresponding to each pixel in the image of the sample, which may increase the electron dose on the sample surface, resulting in surface charging artifacts or other detrimental effects. Such measures may also lower the overall throughput of the inspection system.

In a related art, particle counting may be useful in low-current applications. Particle counting may be employed in detectors such as an Everhart-Thornley detector (ETD), which may use a scintillator and a photomultiplier tube (PMT). An ETD may exhibit good SNR in probe current ranges of some applications, such as 8 pA to 100 pA. However, the scintillator's light yield may degrade with accumulated electron dose, and thus has a limited lifetime. Aging of the scintillator may also cause performance drift at the system level and may contribute to generating non-uniform images. Therefore, an ETD may not be appropriate for use in an inspection tool, especially when used in semiconductor manufacturing facilities where it may be required to run 24 hours per day, 7 days per week.

A charged particle detector is needed that can achieve high SNR and that may be used with low probe currents, such as those below 200 pA. Meanwhile, a detector should secure stable quantum efficiency and long lifetime with low performance drift, for example even when used with probe currents of 1 nA or more in continuous operation.

Detection systems employing related art methods may face limitations in detection sensitivity and SNR, particularly at low electron dosages. Furthermore, in some applications, additional information besides beam intensity may be desired. Some related art systems may employ an energy filter, such as a filter electrode, to filter out some charged particles having a certain level of energy. This may be useful to derive additional information from a sample. However, energy filters may add additional complexity to systems, and may cause SNR to deteriorate due to loss introduced by the energy filter. Improvements in detection systems and methods are thus desired.

### SUMMARY

Embodiments of the present disclosure provide systems and methods for charged particle detection.

According to an embodiment of the invention, there is provided a detector for a charged particle apparatus comprising:
a sensing element including a diode; and
a circuit configured to detect an electron event caused by an electron impacting the sensing element,
wherein the circuit comprises a voltage monitoring device and a reset device,
wherein the reset device is configured to regularly reset the diode by setting a voltage across the diode to a predetermined value,
and wherein the voltage monitoring device is connected to the diode to monitor a voltage across the diode in between resets.

According to another embodiment of the invention, there is provided a method comprising: regularly resetting a diode of a sensing element by setting a voltage across the diode to a predetermined value; and monitoring a voltage across the diode in between resets, wherein the diode is operated in open-circuit mode.

According to a further embodiment of the invention, there is provided a detector array for a charged particle apparatus with multiple beamlets, comprising a plurality of detectors, wherein each of the detectors is associated with a different beamlet and comprises:
a plurality of sensing elements, wherein each sensing element includes a diode;
a plurality of circuits; and
a summing circuit,
wherein each of the circuits corresponds to a sensing element and is configured to detect and count an electron event caused by an electron impacting the corresponding sensing element,
wherein each of the circuits comprises a voltage monitoring device, a reset device, and a device to store the count,
and wherein the summing circuit is configured to sum the electron event counts of the circuits of the corresponding detector.

According to yet another embodiment of the invention, there is provided a diode architecture including:
a substrate;
a sensing element including a diode formed in or on the substrate; and
at least a part of a circuit formed in or on the substrate and configured to detect an electron event caused by an electron impacting the sensing element, wherein an avalanche region is provided between the diode and the circuit.

According to another embodiment of the invention, there is provided a diode architecture including:
a substrate;
a sensing element including a diode formed in or on the substrate; and
at least a part of a circuit formed in or on the substrate and configured to detect an electron event caused by an electron impacting the sensing element,
wherein the diode and the circuit are arranged at a front side of the substrate,
wherein the sensing element comprises a sensing area connected to the diode and arranged at a backside of the substrate opposite the front side to receive electrons causing an electron event, and wherein an avalanche region is provided at the sensing area.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings in which:

FIG. 1 is a schematic diagram illustrating an exemplary electron beam inspection (EBI) system, consistent with embodiments of the present disclosure.

FIG. 2A, FIG. 2B, and FIG. 2C are schematic diagrams illustrating exemplary electron beam tools, consistent with embodiments of the present disclosure that may be a part of the exemplary electron beam inspection system of FIG. 1.

FIG. 3A is a representation of an exemplary structure of a detector, consistent with embodiments of the present disclosure.

FIG. 3B and FIG. 3C are diagrams illustrating cross-sectional views of detectors, consistent with embodiments of the present disclosure.

FIG. 3D and FIG. 3E are diagrams illustrating cross-sectional views of individual detector elements, consistent with embodiments of the present disclosure.

FIG. 3F is a diagram illustrating a detector, consistent with embodiments of the present disclosure.

FIG. 3G is a representation of an exemplary structure of a detector, consistent with embodiments of the present disclosure.

FIG. 4A is a view of a portion of FIG. 2B showing secondary electrons being projected toward a detector from a sample.

FIG. 4B illustrates an example of secondary electron landing point distribution on a detector surface, consistent with embodiments of the present disclosure.

FIG. 5 is a schematic representation of a detector according to an embodiment of the invention including a diode as part of a sensing element and a circuit configured to detect an electron event caused by an electron impacting the sensing element.

FIG. 6 illustrates an example of signal diagrams at different locations in the detector of FIG. 5.

FIG. 7 is a schematic representation of a detector according to another embodiment of the invention including a diode as part of a sensing element and a circuit configured to detect an electron event caused by an electron impacting the sensing element.

FIG. 8 illustrates an example of signal diagrams at different locations in the detector of FIG. 7.

FIG. 9 depicts a schematic of a diode architecture that can be used as a sensing element in accordance with an embodiment of the invention.

FIG. 10 depicts a schematic of a diode architecture that can be used as a sensing element in accordance with another embodiment of the invention.

FIG. 11 depicts a schematic representation of a portion of an element in a MEMS-based miniature SEM array according to a further embodiment of the invention.

FIG. 12 depicts a schematic representation of a detector array according to yet another embodiment of the invention.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims.

Aspects of the present application relate to systems and methods for charged particle beam detection. Systems and methods may employ counting of charged particles, such as electrons, and may be useful in an inspection tool, such as a scanning electron microscope (SEM). Inspection tools may be used in the manufacturing process of integrated circuit (IC) components. To realize the enhanced computing power of modern day electronic devices, the physical size of the devices may shrink while the packing density of circuit components, such as, transistors, capacitors, diodes, etc., is significantly increased on an IC chip. For example, in a smartphone, an IC chip (which may be the size of a thumbnail) may include over 2 billion transistors, the size of each transistor being less than 1/1,000th of a human hair. Not surprisingly, semiconductor IC manufacturing is a complex process, with hundreds of individual steps. Errors in even one step have the potential to dramatically affect the functioning of the final product. Even one “killer defect” can cause device failure. The goal of the manufacturing process is to improve the overall yield of the process. For example, for a 50-step process to get 75% yield, each individual step must have a yield greater than 99.4%, and if the individual step yield is 95%, the overall process yield drops to 7%.

It is increasingly important to ensure the ability to detect defects with high accuracy and high resolution while maintaining high throughput (defined as the number of wafer processes per hour, for example). High process yields and high wafer throughput may be impacted by the presence of defects, especially when operator intervention is involved. Thus, detection and identification of micro and nano-sized defects by inspection tools (such as a SEM) is important for maintaining high yields and low cost.

In some inspection tools, a sample may be inspected by scanning a beam of high energy electrons over the sample surface. Due to interactions at the sample surface, secondary or backscattered electrons may be generated from the sample that may then be detected by a detector.

Related art detectors may have limitations, for example poor signal-to-noise ratio (SNR) or poor durability, as noted above. Aspects of the present disclosure may address some such limitations by providing a detector with one or more detector elements, each of the detector elements including a sensing element with a diode. The detector may include circuitries coupled to each sensing element that may enable the detection of a charged particle event caused by a charged particle impacting the sensing element. The circuitries may be configured to detect a charge or voltage drop across the diode when operated in open-circuit mode instead of detecting a current when the diode is operated in short-circuit mode. Charged particle detection with the diode in open-circuit mode may allow simpler and smaller components to be packaged on a chip relative to, for example, analog signal detection, thus allowing robust and reliable detection of charged particles with less power consumption and good SNR. While the present disclosure discusses some exemplary embodiments in the context of electrons, it will be understood that the present disclosure may be applicable to other types of charged particles, such as ions.

To help ensure accurate electron counting, time separation between subsequent electron arrival events may be a significant parameter. If electron arrival events are too close together, a detector may be overwhelmed, and discrimination of single electron arrival events may be impeded. Similarly, signal pulse width may be another significant parameter limiting electron counting, which may be related to pulse width of signals generated in response to an electron arrival event at the detector. If the detector generates a signal that is too weak or broad (as opposed to a sharp blip), signals from subsequent electron arrival events may merge into one. Additionally, a sampling rate of the detector should be high enough that individual electron arrival events may be captured. That is, a detector should be fast enough that electron arrival events do not go undetected. Another consideration for electron counting may be achieving accuracy with a level of miscounts that may be no more than a certain degree. Miscounts may be based on dead time of a detector element. Thus, a number of criteria may be relevant in configuring a detector for electron counting.

Without limiting the scope of the present disclosure, some embodiments may be described in the context of providing detectors and detection methods in systems utilizing electron beams. However, the disclosure is not so limited. Other types of charged particle beams may be similarly applied. Furthermore, systems and methods for detection may be used in other imaging systems, such as optical imaging, photon detection, x-ray detection, ion detection, etc.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C.

As used throughout the present disclosure, the term “detector element” may include or cover “sensing element,” “sensor element,” “detection cell,” or “detector segment,” etc. A sensing element may be a diode configured to have a depletion region. A detector element may include a diode, an interconnect, and a circuit, which may include front-end electronics, for example. Furthermore, the term “frame” may include or cover “sampling period,” “SEM image pixel period,” or “pixel period,” etc. A SEM image frame may refer to a frame of pixels that may be refreshed on a frame-by-frame basis, while a data frame may refer to a group of data acquired by a detection system within a specified period of time.

Embodiments of the present disclosure may provide a detection method. The detection method may comprise charged particle counting. For example, in some embodiments, a charged particle detection method may be provided for electron microscopy. The method may be applied to a SEM detection system. The charged particle detection method may be based on electron counting. By counting the number of electrons received during a pre-defined period, the intensity of an incoming electron beam may be determined. The term “incoming electron” may include or cover an incident electron, such as an electron that impacts the surface of a detector. According to some embodiments, noise from the charged particle detection process may be reduced. However, solely improving SNR may not fulfill the ever increasing needs of various SEM applications.

Electron counting may involve determining individual electron arrival events occurring at a detector. For example, electrons may be detected one-by-one as they reach the detector. In some embodiments, electrons incident on a detector may generate an electrical signal that is routed to signal processing circuitries and then read-out to an interface, such as a digital controller. A detector may be configured to resolve signals generated by incident electrons and distinguish individual electrons with a discrete count.

In some embodiments, electron counting may be applied to situations in which beam current is very small. For example, an electron beam may be set to irradiate a sample with a low dose. Low current may be used to prevent oversaturation of an electron counting detector by large current. For example, large current may have the effect of introducing nonlinearity in detection results. Meanwhile, for a detector that may be used in an industrial setting, the detector should also be able to handle situations of large beam current.

Some embodiments may address the above issues. For example, some embodiments may provide a plurality of relatively small sensing elements that may be used to detect an electron beam. Isolation may be provided between adjacent sensing elements so that the probability of one incoming electron going from one sensing element to its adjacent sensing elements may be reduced. In this way, crosstalk between adjacent sensing elements may be reduced. Isolation may be provided by deep trench isolation, which has the advantage that it takes limited area and thus allows a high so-called fill factor and is much more efficient isolation than for instance p-n-junctions.

In some embodiments, a data frame rate may be set based on a first parameter. The data frame rate may be a rate of data frames during which sensing elements collect incoming electrons from an electron beam to be used for imaging. The data frame rate may be set so that a pre-defined proportion (e.g., A %) of the sensing elements receive at least one incoming electron. The data frame rate may also be expressed by period (e.g., a duration) of the data frame. In addition, the data frame rate may be set based on a second parameter. For example, among sensing elements that receive at least one incoming electron, only a second pre-defined proportion (e.g., B %) of the sensing elements may receive more than one electron. In this way, a predefined detection linearity may be maintained while, at the same time, electron beams with large beam current may be handled. The data frame rate may be a constant value for a particular SEM setting or may be a varying value set to adapt the signal intensity of the electron beam being detected even under the same SEM settings. As a result, under the same SEM settings, adjacent data frame periods in time domain may be the same or may be different.

In addition to an adaptive frame, each frame may include information about when the frame starts and when it stops. Information on frame start and stop time (e.g., a frame start time point and a frame stop time point) may be used when a pixel in a SEM image is generated. For example, each pixel in a SEM image may be generated using the frames acquired during a particular period of time. The period (or rate) of SEM image pixel acquisition may be based on a predefined parameter set according to specific requirements. During the period of each SEM image pixel acquisition, one or more frames may be acquired. The number of frames acquired in adjacent SEM image pixel periods may be the same or different.

In addition to the frame-rate adjustments, systems and methods for charged particle detection may employ adjustments to structures or settings of a SEM system. For example, to ensure the predefined A % of sensing elements among the group of sensing elements receiving only one electron during the period of each frame, adjustments to the SEM system may be done so that the electron density within each electron beam spot is more evenly distributed. One such adjustment may be to defocus a projection system in a secondary SEM column in a multi-beam inspection (MBI) system. The projection system may be configured to defocus the beam to a certain extent. Furthermore, the magnification of the SEM system may be changed to enlarge the spot size of an electron beam or beamlet(s). The size of each beamlet spot may be enlarged. Magnification settings may be configured in consideration of crosstalk between beamlet spots.

In some embodiments, statistical analysis may be performed at each frame. For example, after each frame, for each electron beam, statistical results of received electron energy plotted against a number of electrons at each energy level within the frame may be acquired in addition to the overall number of electrons received during the frame. The overall numerical output may be used in generating one pixel in a SEM image, such as a grayscale image as in a conventional SEM. The overall number of electrons may correspond to the gray level of the pixel. In this way, an additional degree of freedom may be added to SEM imaging. Accordingly, analysis of a sample may be enhanced by, for example, elucidating further aspects of the sample under investigation such as material properties, microstructure, and alignment between layers.

In some embodiments, a detection method may be applied to grayscale SEM imaging. The method may comprise determining a series of thresholds. Instead of or in addition to generating statistical results of received electron energy plotted against a number of electrons at each energy level within the frame, information may be generated with respect to the thresholds. For example, three thresholds may be set in a way that the electron energy increases from low to high. The first threshold at the lowest electron energy may be used to identify whether a sensing element has received an electron or if its output is caused by interference or dark current, or the like. The second threshold, with an intermediary electron energy, may be used to identify whether an electron received by a sensing element is a secondary electron from the sample or a scattered electron from the sample. The third threshold, with the highest electron energy, may be used to identify whether a sensing element has received more than one electron during the specific frame. The number of secondary electrons received, the number of the scattered electrons received, and overall number of electrons received during the specific frame may be determined. By accumulating the above information pixel-by-pixel for a SEM image, one or more of the following can be acquired: a SEM image based on all received electrons, a secondary electron SEM image, and a scattered electron SEM image. Such images may be acquired with improved signal-to-noise ratio and without the help of an energy filter.

In some embodiments, a detector may be formed by using digital circuitry rather than implementations requiring a large amount of analog circuits. Accordingly, various aspects of implementation of a detector, such as design and manufacturing, may be improved.

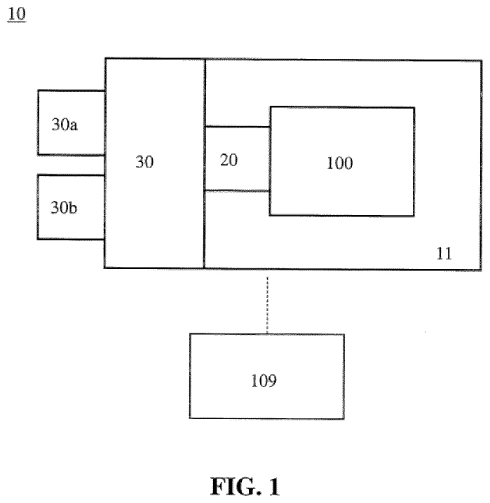

Reference is now made to FIG. 1, which illustrates an exemplary electron beam inspection (EBI) system 10 that may include a detector, consistent with embodiments of the present disclosure. EBI system 10 may be used for imaging. As shown in FIG. 1, EBI system 10 includes a main chamber 11 a load/lock chamber 20, an electron beam tool 100, and an equipment front end module (EFEM) 30. Electron beam tool 100 is located within main chamber 11. EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

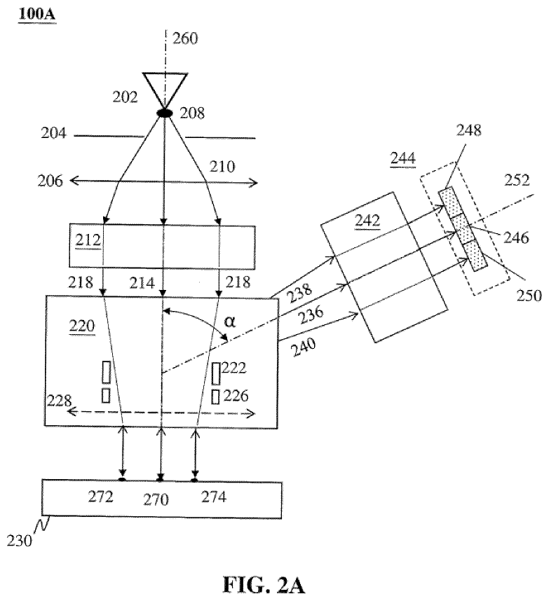

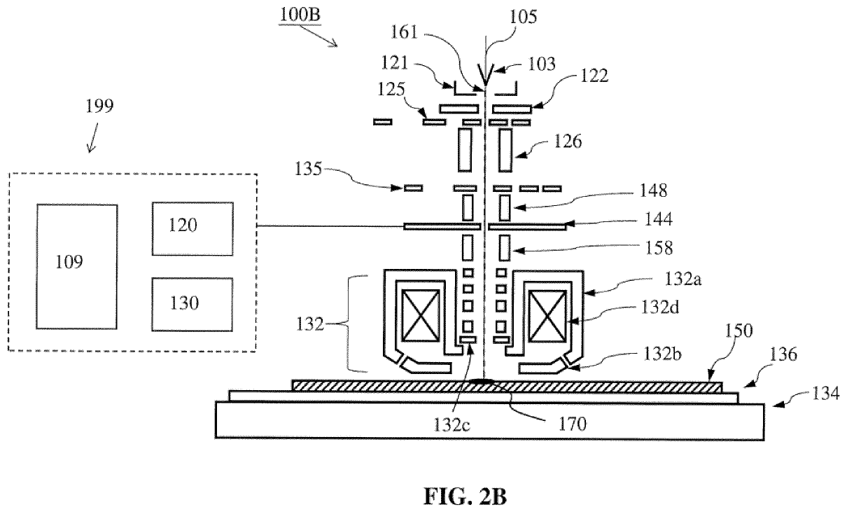

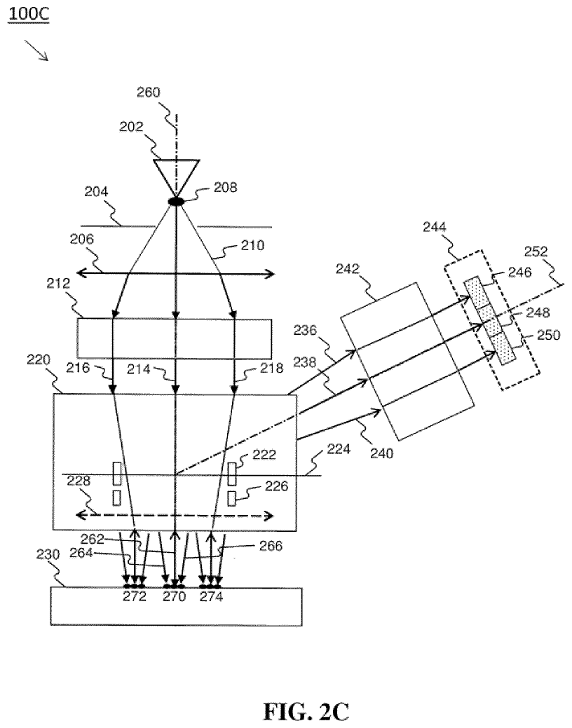

FIG. 2A illustrates a charged particle beam apparatus in which an inspection system may comprise a multi-beam inspection tool that uses multiple primary electron beamlets to simultaneously scan multiple locations on a sample.

As shown in FIG. 2A, an electron beam tool 100A (also referred to herein as apparatus 100A) may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and an electron detection device 244. Electron source 202 may generate primary particles, such as electrons of primary electron beam 210. A controller, image processing system, and the like may be coupled to electron detection device 244. Primary projection optical system 220 may comprise a beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 252 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be a moveable condenser lens that may be configured so that the position of its first principle plane is movable. The movable condenser lens may be configured to be magnetic, which may result in off-axis beamlets 216 and 218 landing on the beamlet-limit apertures with rotation angles. The rotation angles change with the focusing power and the position of the first principal plane of the movable condenser lens. In some embodiments, the moveable condenser lens may be a moveable anti-rotation condenser lens, which involves an anti-rotation lens with a movable first principal plane. Moveable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over a surface area of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230.

Although FIG. 2A shows an example of electron beam tool 100 as a multi-beam tool that uses a plurality of beamlets, embodiments of the present disclosure are not so limited. For example, electron beam tool 100 may also be a single-beam tool that uses only one primary electron beam to scan one location on a wafer at a time.

As shown in FIG. 2B, an electron beam tool 100B (also referred to herein as apparatus 100B) may be a single-beam inspection tool that is used in EBI system 10. Apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

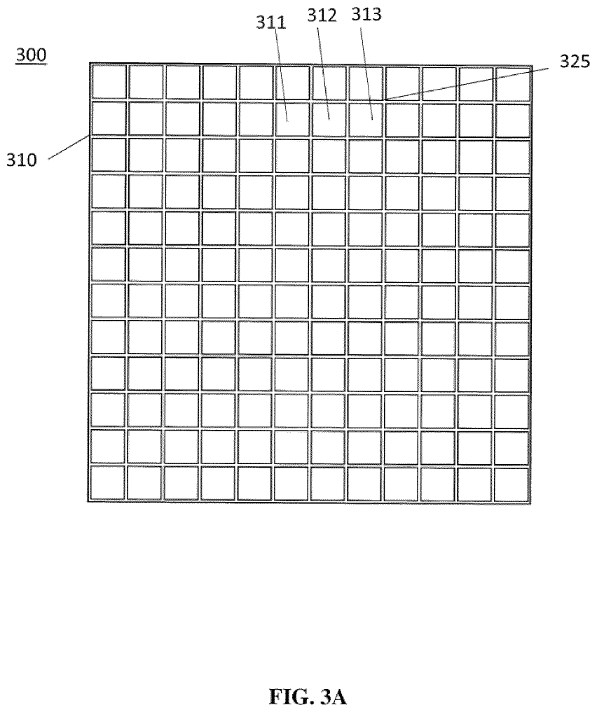

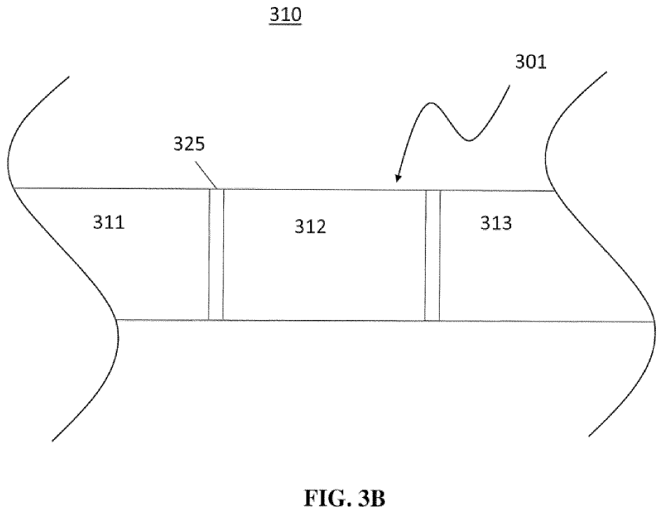

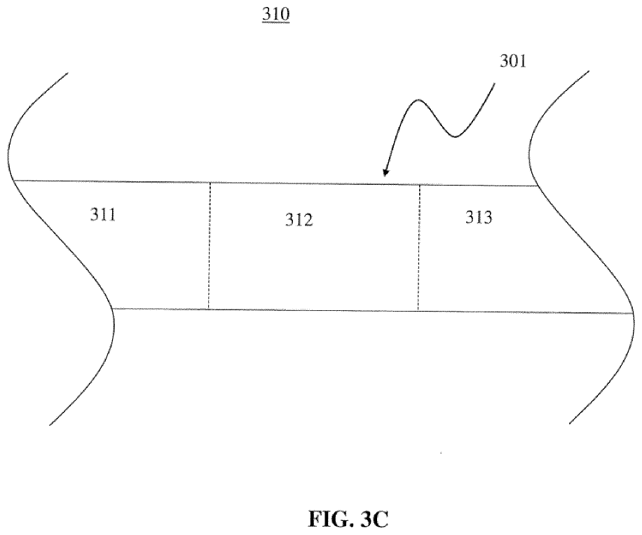

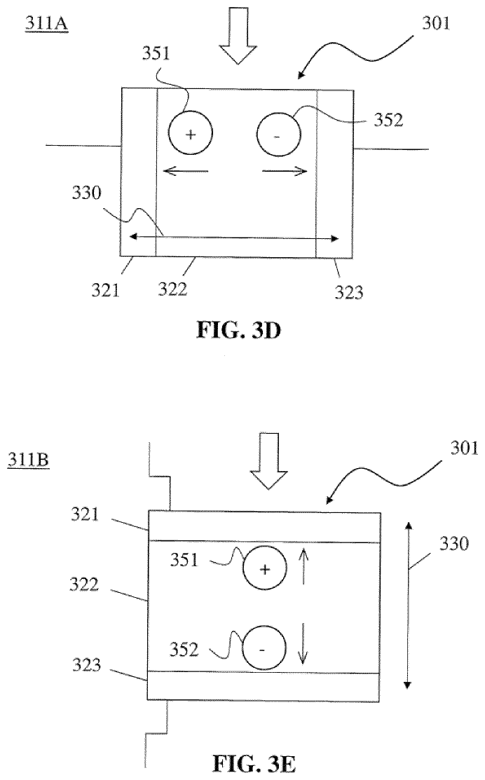

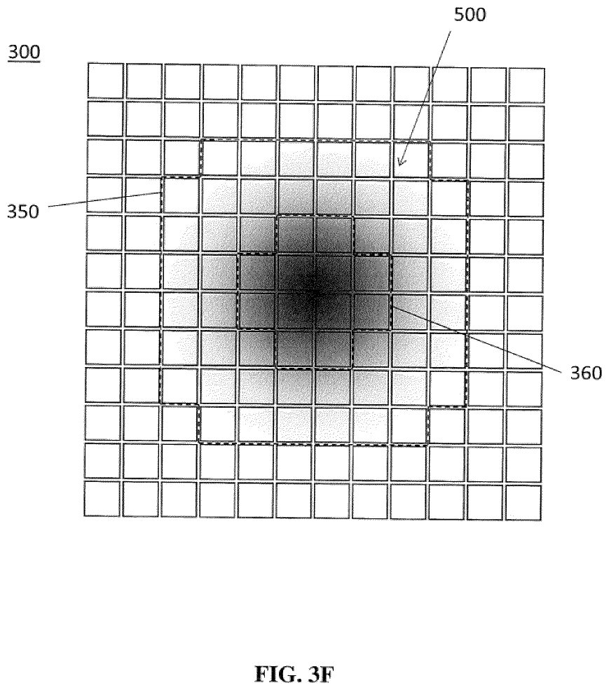

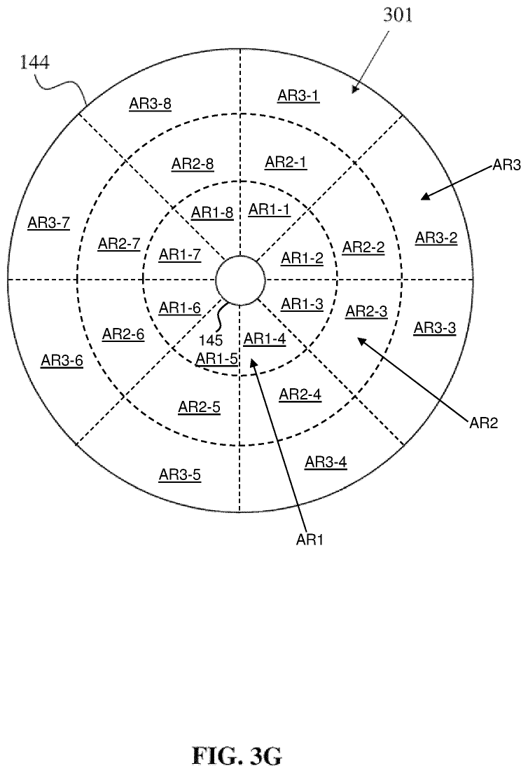

FIG. 2B illustrates a charged particle beam apparatus in which an inspection system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 3G shows an example of detector 144 having an opening 145 at its center. However, some embodiments may use a detector placed off-axis relative to the optical axis along which the primary electron beam travels. For example, as in the embodiment shown in FIG. 2A, beam separator 222 may be provided to direct secondary electron beams toward a detector placed off-axis. Beam separator 222 may be configured to divert secondary electron beams by an angle α.

Another example of a charged particle beam apparatus will now be discussed with reference to FIG. 2C. Electron beam tool 100C (also referred to herein as apparatus 100C) may be an example of electron beam tool 100 and may be similar to electron beam tool 100A shown in FIG. 2A.

As shown in FIG. 2C, beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. For a dispersion plane 224 of beam separator 222, FIG. 2C shows dispersion of beamlet 214 with nominal energy V0 and an energy spread ΔV into beamlet portions 262 corresponding to energy V0, beamlet portion 264 corresponding to energy V0+ΔV/2, and beamlet portion 266 corresponding to energy V0−ΔV/2. The total force exerted by beam separator 222 on an electron of secondary electron beams 236, 238, and 240 can be non-zero. Beam separator 222 may separate secondary electron beams 236, 238, and 240 from beamlets 214, 216, and 218 and direct secondary electron beams 236, 238, and 240 towards secondary optical system 242.

A semiconductor electron detector may be used in apparatus 100 in EBI system 10. EBI system 10 may be a high-speed wafer imaging SEM including an image processor. An electron beam generated by EBI system 10 may irradiate the surface of a sample or may penetrate the sample. EBI system 10 may be used to image a sample surface or structures under the surface, such as for analyzing layer alignment. In some embodiments, EBI system 10 may detect and report process defects relating to manufacturing semiconductor wafers by, for example, comparing SEM images against device layout patterns, or SEM images of identical patterns at other locations on the wafer under inspection. A detector may include a silicon PIN diode that may operate with negative bias, so that the detector may alternatively be referred to as a PIN detector. A PIN detector may be configured so that incoming electrons generate a relatively large and distinct detection signal. In some embodiments, a PIN detector may be configured so that an incoming electron may generate a number of electron-hole pairs while a photon may generate just one electron-hole pair. A PIN detector used for electron counting may have numerous differences as compared to a photodiode used for photon detection, as shall be discussed as follows.

Reference is now made to FIG. 3A, which illustrates a schematic representation of an exemplary structure of a detector 300. Detector 300 may be provided as detector 144 or electron detection device 244 with reference to FIG. 2A, FIG. 2B, and FIG. 2C. While one array is shown in FIG. 3A, it is appreciated that detector 300 may include multiple arrays, such as one array for each secondary electron beam.

Detector 300 may comprise an array of sensing elements, including sensing elements 311, 312, and 313. The sensing elements may be arranged in a planar, two-dimensional array, the plane of the array being substantially perpendicular to an incidence direction of incoming charged particles. In some embodiments, detector 300 may be arranged so as to be inclined relative to the incidence direction.

Detector 300 may comprise a substrate 310. Substrate 310 may be a semiconductor substrate that may include the sensing elements. A sensing element may comprise a diode. A sensing element may also be an element similar to a diode that can convert incident energy into a measurable signal. The sensing elements may comprise, for example, a PIN diode, an avalanche diode, etc., or combinations thereof. An area 325 may be provided between adjacent sensing elements. Area 325 may be an isolation area to isolate the sides or corners of neighboring sensing elements from one another. Area 325 may comprise an insulating material that is a material different from that of other areas of the detection surface of detector 300. Area 325 may be provided as a cross-shaped area as seen in the plane view of FIG. 3A. Area 325 may be provided as a square. In some embodiments, area 325 may not be provided between adjacent sides of sensing elements. For example, in some embodiments, there may be no isolation area provided on a detection surface of a detector.

Sensing elements may generate an electric signal commensurate with charged particles received in the active area of a sensing element. For example, a sensing element may generate an electric voltage signal commensurate with the energy of a received electron. The voltage signal may represent the intensity of an electron beam spot or a part thereof. In some embodiments, signal processing circuitry may be provided that provides an output signal in arbitrary units on a timewise basis. There may be provided one or a plurality of substrates, such as dies, that may form circuit layers for processing the output of sensing elements. The dies may be stacked together in a thickness direction of the detector. Other circuitries may also be provided for other functions. For example, switch actuating circuitries may be provided that may control switching elements for connecting sensing elements to one another.

Reference is now made to FIG. 3B, which shows a schematic illustration of a cross-sectional structure of a substrate 310, which may be an example of a structure included in a PIN detector. Substrate 310 may comprise one or more layers. For example, substrate 310 may be configured to have a plurality of layers stacked in a thickness direction, the thickness direction being substantially parallel to an incidence direction of an electron beam. In some embodiments, substrate 310 may have a plurality of layers stacked in a direction perpendicular to the incidence direction of an electron beam. Substrate 310 may be provided with a sensor surface 301 for receiving incident charged particles. Sensing elements (for example sensing elements 311, 312, and 313) may be provided in a sensing layer of substrate 310. Area 325 may be provided between adjacent sensing elements. For example, substrate 310 may comprise a trench, or other structure that is made of or filled with insulating material. In some embodiments, area 325 may extend fully or partially through substrate 310. In other words, the insulating material may extend from one surface to a certain depth.

As shown in FIG. 3C, in some embodiments, area 325 may not be provided between sensing elements. For example, there may be no insulating material provided between the sides of adjacent sensing elements in cross-sectional view. The plurality of sensing elements may be contiguous in cross-sectional view. Isolation between adjacent sensing elements may still be achieved by other means, such as by controlling electrical field. For example, electrical field may be controlled between each sensing element.

Although the figures may show sensing elements 311, 312, and 313 as discrete units, such divisions may not actually be present. For example, the sensing elements of a detector may be formed by a semiconductor device constituting a PIN diode device. The PIN diode device may be manufactured as a substrate with a plurality of layers including a p-type region, an intrinsic region, and an n-type region. One or more of such layers may be contiguous in cross-sectional view. In some embodiments, however, sensing elements may be provided with physical separation between them. Further layers may also be provided in addition to the sensor layer, such as a circuit layer, and a read-out layer, for example.

As one example of a further layer, detector 300 may be provided with one or more circuit layers adjacent to the sensor layer. The one or more circuit layers may comprise line wires, interconnects, and various electronic circuit components. The one or more circuit layers may comprise a processing system. The one or more circuit layers may comprise signal processing circuitries. The one or more circuit layers may be configured to receive the output charge or voltage detected from sensing elements in the sensor layer. The one or more circuit layers and the sensor layer may be provided in the same or separate dies, for example.

FIGS. 3D and 3E show schematic illustrations of individual sensing elements, which may be an example of one of sensing elements 311, 312, and 313. For example, in FIG. 3D, a sensing element 311A is shown. Sensing element 311A may include a semiconductor structure of a p-type layer 321, an intrinsic layer 322, and an n-type layer 323. Sensing element 311A may include two terminals, such as an anode and a cathode. Sensing element 311A may be reverse biased, and a depletion region 330 may form and may span part of the length of p-type layer 321, substantially the entire length of intrinsic layer 322, and part of the length of n-type layer 323. In depletion region 330, charge carriers may be removed, and new charge carriers generated in depletion region 330 may be swept away according to their charge. For example, when an incoming charged particle reaches sensor surface 301, electron-hole pairs may be created, and a hole 351 may be attracted toward p-type layer 321 while an electron 352 may be attracted toward n-type layer 323. In some embodiments, a protection layer may be provided on sensor surface 301.

As shown in FIG. 3E, a sensing element 311B may operate in a similar manner to that of sensing element 311A except that an orientation is changed. For example, p-type layer 321 may include sensor surface 301. P-type layer 321 may be exposed to incident charged particles. Thus, an incident charged particle may interact with p-type layer 321 and depletion region 330, and may generate electron-hole pairs. In some embodiments, a metal layer may be provided on top of p-type layer 321.

In operation, a depletion region of a detection element may function as a capture region. An incoming charged particle may interact with the semiconductor material in the depletion region and generate new charges. For example, the detection element may be configured such that a charged particle having a certain amount of energy or greater may cause electrons of the lattice of the semiconductor material to be dislodged, thus creating electron-hole pairs. The resulting electrons and holes may be caused to travel in opposite directions due to, for example, an electric field in the depletion region. Generation of carriers that travel toward terminals of the sensing element may correspond to current flow in or voltage drop across the detection element.

In a comparative example, a photodiode may be configured to generate electric charge in response to receiving photons. A photon may have energy that corresponds to its wavelength or frequency. Typically, a photon in the visible light spectrum may have energy on the order of about 1 eV. However, in a semiconductor photodiode, it is typical that about 3.6 eV may be required to generate one electron-hole pair. Therefore, photodiodes may encounter difficulties in detecting current generation such as the following.

In general, a level of energy of a photon may be similar to that required to generate an electron-hole pair in a semiconductor photodiode. Thus, in order to generate electric signal stably and reliably, it may be necessary that photons of high energy be incident on a semiconductor photodiode. A photon may have energy sufficient to generate one electron-hole pair when its frequency is at or above a certain level.

Furthermore, the electric signal generated by electron-hole pairs in response to photon arrival events may be relatively low. Electric signals generated in response to photon arrival events may not be sufficient to overcome background noise. Some diodes, such as a photodiode biased to avalanche or Geiger counting mode, may employ amplification to generate a larger level of electric signal so that a useful detection signal can be generated. In some embodiments, a photodiode may be biased to avalanche operation mode. In some embodiments, amplification may be provided by gain blocks attached to the photodiode. An avalanche effect may be generated from strong internal electric fields resulting from bias voltage. The avalanche effect may be used to achieve amplification due to impact ionization.

Background noise in a detector may be caused by, among other things, dark current in a diode. For example, imperfections in a crystal structure of a semiconductor device acting as a diode may cause current fluctuation. Dark current in a detector may be due to defects in materials forming the detector and may arise even when there is no incident irradiation. “Dark” current may refer to the fact that current fluctuation is not related to any incoming charged particle.

A diode may be configured to generate electron-hole pairs when a particle (e.g., a photon) with no less than a certain level of energy enters the diode. For example, a photodiode may only generate an electron-hole pair when a photon with no less than a certain level of energy enters the photodiode. This may be due to, for example, the band gap of the materials that form the photodiode. A photon with energy equal to the certain level may be able to generate only one electron-hole pair, and even if a photon has more energy exceeding the certain level, it still may only generate one electron-hole pair. No additional electron-hole pairs may be generated. Meanwhile, an electron detector may be configured so that whenever an electron enters the depletion region of a detector sensing element, which may include a diode, as long as the electron has energy of not less than a certain amount, e.g., about 3.6 eV, electron-hole pairs may begin to be generated. If the electron has more energy than the certain amount, more electron-hole pairs may be generated during the arrival event of the incoming electron.

In a diode configured for photon detection, defects in the diode may cause random generation of electron-hole pairs in the diode due to, for example, imperfections in a crystal lattice of a semiconductor structure. Dark current may be amplified by amplification effects, such as an avalanche amplification. The signal resulting from dark current may go on to be input into a counting circuit where it may be recorded as an arrival event. Such an event may be referred to as a “dark count.” Furthermore, amplifiers themselves may contribute to noise. Therefore, various sources of noise, such as dark current, thermal energy, extraneous radiation, etc., may cause unintended current fluctuations in a detector's output.

In contrast to a photon, an electron may have significantly more energy that may be useful in generating signals in a diode. Incident electrons on a sensing element of a detector may have significantly more energy than a threshold level of energy necessary to generate an electron-hole pair in the sensing element. Accordingly, incident electrons may generate numerous electron-hole pairs in a sensing element.

Reference is now made to FIG. 3F, which shows an exemplary view of a charged particle beam spot 500 received on detector 300. Beam spot 500 may have a round shape with no loci offset, as illustrated. In some embodiments, the beam spot may have a shape other than round. For example, in a single beam system, a beam spot may have a shape that deviates from a circular shape due to aberration. Furthermore, in some embodiments, multiple beam spots may be incident on a detector, such as in a multi-beam system. Beam spots may deviate from a round shape in terms of, for example, location, shape, and grid spacing (e.g., the pitch between beam spots when multiple beam spots are formed). Deviations may be due to aberration, dispersion, drift in an electron optical system, or imperfections of components, for example.

In some embodiments, a detection system may include a controller that may be configured to determine that charged particles are incident on a detector. The controller may be configured to determine a number of charged particles incident on sensing elements of the detector within a frame. For example, the controller may perform charged particle counting, such as electron counting. Charged particle counting may be done frame-by-frame. The detector may be configured such that individual sensing elements (such as sensing elements 311, 312, and 313 of FIG. 3A) output a detection signal on a timewise basis. The detection signal may be transmitted to the controller. The detection signal may be, for example, a signal in amperes, volts, or arbitrary units commensurate with energy of electrons received at the respective sensing element. The controller may determine, based on the detection signal, that a discrete number of charged particles arrive at a sensing element. The number of charged particles may be discerned as a whole number.

The controller may be configured to determine a first group of sensing elements among the plurality of sensing elements provided in the detector based on a first grouping criteria. The first grouping criteria may comprise a condition that, for example, at least one charged particle is incident on each of a first number of sensing elements of the detector. The first number may be in terms of a raw number or a proportion of sensing elements. The controller may be configured to make the determination of the first group on a timewise basis within a period of one frame. The determination may be made repeatedly over a plurality of frames, such that the controller has a frame rate for performing processing, such as making charged particle counting determinations within each frame. The controller may also determine a boundary line. For example, as shown in FIG. 3F, a boundary line 350 may be determined. Boundary line 350 may be provided so as to encompass sensing elements that receive at least one charged particle. The sensing elements contained within boundary line 350 may be covered, at least partially, by the same charged particle spot.

Beam spot 500 may have a well-defined center, or locus. Near the center of beam spot 500, the intensity may be higher than near the outer periphery. The difference in intensities may be attributed to various factors including tip size of electron source 202, aberration of the electron optics system, electron dispersion, and other parameters of apparatus 100A, etc. Moreover, in some embodiments, variations in intensities may be caused by the sample topography of scattered electrons, material (for example in the case of back-scattered electrons), charging conditions on the sample surface, landing energy, etc. Thus, areas of high intensity may not necessarily be at the center of beam spot 500.

In areas of beam spot 500 where intensity is higher, there may be more than one electron incident on a sensing element of the detector. Thus, the controller may be configured to determine a second group of sensing elements based on a second grouping criteria. The second grouping criteria may comprise a condition that more than one charged particle is incident on each of a second number of sensing elements. The second group containing the second number of sensing elements may be determined among the first group containing the first number of sensing elements. That is, the second group may be a subset of the first group. The determination of the second group may be made concurrently with the determination of the first group. Thus, determinations of the first group and the second group may be for the same frame. The controller may also determine a second boundary line 360 that encompasses the sensing elements that receive more than one charged particle.

The controller may be configured to determine or adjust a frame rate (or period) of performing processing. The processing may correspond to image processing for generating a SEM image based on output from the detector, for example. The processing may also include determining the first group of sensing elements and the second group of sensing elements, as discussed above. The period of a first frame may be determined based on a first parameter, as follows. The period may be set so that a first predetermined number of sensing elements receive at least one incident charged particle in the first frame. The first predetermined number may be a proportion, for example A %, of sensing elements among all the sensing elements of the detector. The first predetermined number may also be a certain proportion of sensing elements among those in a particular region of the detector, and not necessarily among all of the sensing elements. For example, the first predetermined number may be a proportion of sensing elements in a first quadrant of the detector. The first predetermined number may also be a raw number, such as X sensing elements.

In addition, the period may be set based on a second parameter. The second parameter may be that a second predetermined number of sensing elements each receive more than one incident charged particle in the first frame. For example, the second parameter may be that among sensing elements that receive at least one incident charged particle, only a second proportion, for example B %, of the sensing elements receive more than one charged particle. The second predetermined number may also be a raw number, such as Y sensing elements. Parameters may be adjusted so that the first parameter is satisfied before the second parameter is satisfied.

The first parameter and the second parameter may define boundary conditions for determining the period of the first frame. The first parameter or the second parameter may be used. The first parameter and the second parameter may be used together. In addition to determining a period of the first frame, a frame rate for a plurality of frames may be determined. The frame rate may be a constant value that may be set based on, for example, a particular SEM setting. Thus, the frame rate may be the inverse of the period for the first frame. The frame rate may also be adaptive, that is, having a varying value. The adaptive frame rate may be set to adapt the signal intensity of the charged particle beam being detected.

In some embodiments, electron beam tool 100 may be configured so that the electron density within an electron beam spot is more evenly distributed. For example, controller 109 may control electron optics so that electron beams or beamlets are defocused. The electron optics may adjust the electron beam (or beamlets) so that its focal point is not coincident with the surface of detector 144 or electron detection device 244. Furthermore, a projection system in a secondary SEM column may be configured to defocus the secondary beam (or beamlets) to a certain extent. Additionally, magnification of the projection system in the secondary SEM column may be changed to enlarge the spot size of an electron beam or beamlet(s). The size of each beamlet spot may be enlarged. Magnification settings may be configured in consideration of crosstalk between beamlet spots.

FIG. 3G shows an example of a surface of detector 144 that may include a PIN detector. Detector 144 may include sensor surface 301 arranged so as to receive charged particles generated from a sample. In some embodiments of the disclosure, a PIN detector may be used as an in-lens detector in a retarding objective lens SEM column of EBI system 10. The PIN detector may be placed between a cathode for generating an electron beam and the objective lens. The electron beam emitted from the cathode may be potentialized at −BE keV (typically around −10 kV). Electrons of the electron beam may be immediately accelerated and travel through the column. The column may be at ground potential. Thus, electrons may travel with kinetic energy of BE keV while passing through opening 145 of detector 144. Electrons passing through the pole piece of the objective lens, such as pole piece 132a of objective lens assembly 132 of FIG. 2B, may be steeply decelerated down to landing energy LE keV as the wafer surface potential may be set at −(BE-LE) keV.

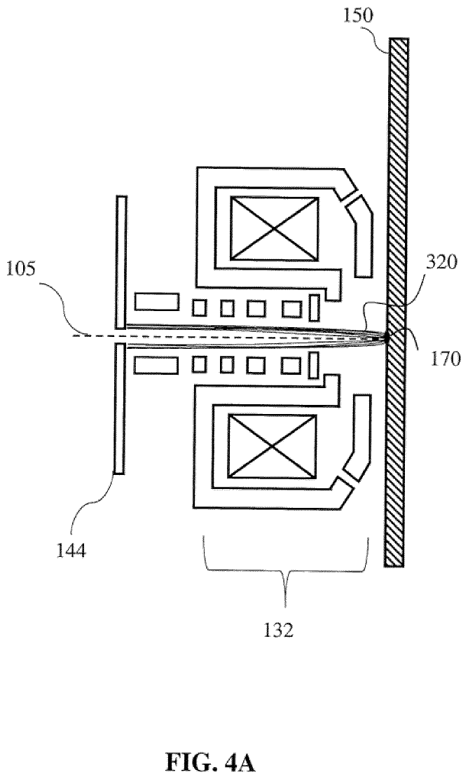

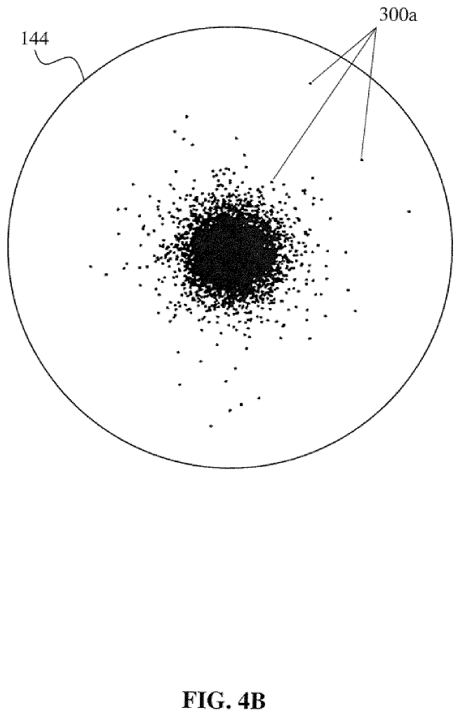

Secondary electrons emitted from the wafer surface by the impingements of electrons of the primary electron beam may be accelerated by an acceleration field (e.g., the retarding electrical field near the wafer may act as an acceleration field for secondary electrons) and travel backwards toward the PIN detector surface. For example, as shown in FIG. 4A, due to interactions with wafer 150 at probe spot 170, secondary electrons may be generated that travel back toward detector 144. Secondary electrons emitted from the wafer surface travelling along optical axis 105 may arrive at the surface of detector 144 with a distribution of positions. The landing positions of secondary electrons may be within a generally circular region with a radius of, for example, a few millimeters. A geometric spread of landing positions of secondary electrons may be due to electrons having different trajectories that may be dependent on, for example, initial kinetic energy and emission angles of the electrons.

FIG. 4B illustrates an example of secondary electron landing point distribution on a detector surface. Electrons 300a may land at different points on the surface of detector 144 while, generally, most may be clustered around the central portion of detector 144. Landing point distribution may shift depending on secondary emission position and SEM deflection fields (e.g., scan field). Therefore, in some applications, if a certain field of view (FOV) of an SEM image is required, the required size of an in-lens PIN detector may be substantially large. Typically, a detector may be 10 mm in diameter, or larger, for example. In some embodiments, a detector may be about 4 to 10 mm in diameter.

Electrons incident on the detection surface of a PIN detector may be converted to an electrical charge. The electrical charge may be collected at a terminal of the PIN detector and used as a detection signal that may be proportional to the incoming electron rate. In an ideal PIN detector, kinetic energy of an incoming electron having energy (BE−LE) keV may be fully consumed by creating numerous electron-hole pairs at a rate of about 3.61 eV per pair. Therefore, for an incoming electron of 10,000 eV energy, approximately 2,700 electron-hole pairs may be created. In contrast to a photon arrival event that may generate just a single electron-hole pair, electron arrival events may generate significantly more electron-hole pairs.

A sensing element may be configured to generate numerous electron-hole pairs in response to an electron arrival event. In some embodiments, electrical charge or voltage generated in response to electron arrival events in a sensing element may be usable as a detection signal. Output of a sensing element in response to an electron arrival event may be used as-is or may undergo relatively small amplification. The need to provide amplification may be reduced or omitted. Omitting or providing reduced amplification may be beneficial for decreasing noise. Furthermore, an amplifier may indiscriminately apply amplification to all signals generated in a diode. Therefore, even so-called “dark counts” may be amplified and may contribute to erroneous detection signals.

In some embodiments according to the disclosure, dark current may generate only small output in comparison to charged particles that a sensing element is configured to detect. For example, dark current may be caused by a dislocation in the crystal lattice of a semiconductor structure of a diode may allow an electron to become dislodged. In some cases, dark current may thus result in only a single electron-hole pair being generated in a sensing element. However, as discussed above, in a sensing element configured to generate numerous electron-hole pairs in response to the arrival of a charged particle, such as a secondary electron, about 3,000 electron-hole pairs may be generated. Thus, there may be a ratio of signal to dark current noise of about 3,000:1.

A semiconductor diode, such as a diode having a PIN structure, may be operated in various modes. For example, in a first mode, the diode may be operated with normal reverse bias. In this mode, each incoming photon with high enough energy may generate only one electron-hole pair. When outside radiation (e.g., incoming photons) disappears, current flow in the diode may stop immediately.

In a second mode of operating a diode, the diode may be operated with higher reverse bias than that in the first mode. The second mode may introduce impact ionization. This may also be referred to as avalanche photodiode mode. In this mode, each incoming photon with high enough energy may generate one electron-hole pair. Then, due to internal impact ionization, this one pair may be multiplied by avalanche gain so that several electron-hole pairs may eventually be generated. Thus, each incoming photon may result in several electron-hole pairs being generated. When outside radiation disappears, current flow in the diode may stop immediately. The second mode may include a linear region and a nonlinear region.

In a third mode of operating a diode, the diode may be operated with even higher reverse bias than that in the second mode. The third mode may introduce stronger impact ionization. The third mode may enable photon counting. The third mode may include Geiger counting mode. In the third mode, each incoming photon with high enough energy may generate one electron-hole pair. Then, due to internal impact ionization, this one pair may be multiplied by the avalanche gain so that several electron-hole pairs may eventually be generated. Thus, each incoming photon may result in several electron-hole pairs being generated. Due to strong internal electric field from high reverse bias voltage, the multiplication process may continue. Multiplication may be self-sustaining. When outside radiation disappears, electron-hole pair generation in the diode may not necessarily stop. Electron-hole pair generation in the diode may be stopped by disconnecting the diode from a power supply. After disconnection, electron-hole pair generation in the diode may then subside. In the third mode, the diode may be provided with a quenching circuit. The quenching circuit may include a passive or an active quenching circuit. Actuating the quenching circuit may allow the diode to be shut down after each photon arrival event. Quenching may be used to reset and/or during a reset of a diode.

A diode may be configured to operate with a level of gain. For example, a diode may be configured to operate with gain below 100. This may refer to a gain imparted by operation of the diode by application of voltage. The gain may amplify a signal up to, for example, 100 times relative to its original strength. It will be appreciated that other specific levels of gain may be used as well.

The use of a gain effect, such as that by a diode biased to avalanche mode or Geiger counting mode, may involve time-dependent phenomena. For example, a diode biased to avalanche mode may impart gain through avalanche multiplication. There may be a finite time associated with the gain effect. A diode may have a speed that is related to the time it takes for the gain effect to occur. A diode biased to avalanche mode, but not to Geiger counting mode, may have a speed that is at least equal to a speed of the diode under normal bias conditions. A diode biased to avalanche mode may also have a speed that is higher than that of the diode under normal bias conditions. In some situations, there may be a recovery time after an arrival event of a charged particle at the diode. A diode operated in Geiger counting mode may have an associated recovery time. Recovery time may limit the ability of a diode to detect discrete signals in close succession. A diode operated in Geiger counting mode may need to be quenched after a charged particle arrival event in order to accurately detect the next event.

If, for example, detectable events occur in close succession, issues may be encountered in applying a gain effect to amplify signals of subsequent events after the first event because an initial avalanche and its related effects are still ongoing. In contrast to a traditional diode operated in avalanche mode, a detector in accordance with some embodiments of the present disclosure may address issues related to recovery time. For example, as shall be discussed in more detail below, a PIN detector may be configured to generate electron-hole pairs with high gain, without requiring reverse biasing to, e.g., avalanche mode or Geiger counting mode. Gain provided in a PIN detector may be related to the kinetic energy of an incoming charged particle, such as an electron. A detector may include a sensing element having a PIN structure and a circuit. The need for providing a quenching circuit may be omitted. A detector may be configured to generate electron-hole pairs corresponding to a pulse lasting about 3 to 5 ns, or less, for example.

In an exemplary PIN detector, holes may be excited in a depletion region in an intrinsic area of the PIN detector and may drift by the field created by reverse bias in the PIN detector toward the anode. Then, the holes may be collected at the anode. Electrons generated in the depletion region may drift in an opposite direction to the holes. Thus, electrons may be collected at the cathode, which may be grounded. The holes and electrons created in the depletion region may be recombined with opposite charges within the PIN detector. The recombination rate may be high outside the depletion region. The depletion region may encompass part of the P+ region, which may act as the anode, due to the reverse bias. Recombination of holes or electrons on the side of the P+ region where incident electrons enter the detector may contribute to energy loss and will not contribute to detector signal at the anode terminal. Therefore, it may be desirable to configure the electrode on the side where incident electrons enter the detector to be thin, e.g., to reduce energy loss. For example, in a PIN detector, it may be desirable to configure the P+ layer thickness to be as thin as possible.

Reverse bias applied to a PIN detector may involve voltage application. A diode may be configured to operate with a reverse voltage of a certain amount or less. In some embodiments, the certain amount may be 100 volts. The diode may be operated within a linear region.

In some embodiments, both secondary electrons and backscattered electrons may reach the detector. For example, in a comparative example, approximately 20 to 30% of incoming electrons on a PIN detector may be back-scattered electrons having energy approximately equal to energy of the electrons in the primary beam (e.g., BE). Back-scattered electrons may be the same electrons included in the primary beam generated by an electron source, only having been reflected back off a sample without losing a substantial amount of energy.

Furthermore, some electrons, not having been back-scattered, may lose their kinetic energy by causing a lattice atom in the PIN detector (e.g., in a silicon substrate, a Si atom) to emit its characteristic X-ray photons. Other excitation, such as phonons, etc., may also be generated. Thus, the number of charges created by a single incoming electron having a fixed kinetic energy may vary. That is, electron gain (e.g., the number of charges collected at the terminals of the diode per incoming electron) may vary between incoming electrons. However, in a typical PIN detector, even if electron gain varies, it should not exceed electron gain for an ideal PIN detector, as discussed above. Typically, the distribution of actual electron gain has a distinct peak at gain 0, representing detection loss due to electron scattering by the Si crystal.

Charges collected at the terminals of the PIN detector may form a voltage signal. The voltage signal may follow the modulation of incoming electron rate as an electron beam scans over a wafer surface.

FIG. 5 schematically depicts a diode 500 as part of a sensing element and a circuit 510 configured to detect an electron event caused by an electron impacting the sensing element. The circuit 510 includes a reset device 511 and a voltage monitoring device 512. The anode side of the diode 500 is connected to V0, which may be ground, while the cathode side of the diode is connected to the reset device 511 and the voltage monitoring device 512.

The reset device 511 is configured to regularly reset the diode 500 by setting a voltage across the diode 500 to a predetermined value, in this example V1−V0, which yields V1 in case V0=0 Volts. In this embodiment, the reset device 511 includes a switch 511a. When the switch 511a is closed, the cathode side of the diode 500 is connected to V1 thereby resetting the diode 500.

The voltage monitoring device 512 is configured to monitor a voltage across the diode 500 at least in between resets caused by the reset device 511. In this embodiment, the voltage monitoring device 512 comprises a comparator 512a that compares a voltage V2 at the cathode of the diode 500 with a reference voltage Vref. An output Vout of the comparator then indicates when the voltage V2 is above or below the reference voltage Vref.

In this embodiment, V1 and V0 are chosen such that when the diode 500 is reset by the reset device 511, the diode 500 is reverse biased. As there is no current flow through the diode 500, the diode 500 is charged similar to a capacitor until the voltage across the diode 500 equals V1−V0. After resetting the diode 500, the switch 511a is opened thereby disconnecting the cathode side of the diode 500 from the voltage V1. In an ideal situation, the circuit is configured to maintain the voltage across the diode 500 at the level V1−V0 as set by the reset device 511. As mentioned above, electrons incident to the sensing element will create one or more electron-hole pairs and cause a change of the charge and thus voltage across the diode 500. With V1>V0 and the diode being operated in reverse bias, the generated electron-hole pairs will cause a voltage drop over the diode 500 and thus a lowering of voltage V2. When the voltage drop is large enough to cause the voltage V2 to drop below Vref, the output Vout of the comparator will change thereby indicating the occurrence of at least one electron event. Subsequent resetting of the diode 500 using the reset device 511 will restore the voltage across the diode 500 to the V1−V0 level and thus also reset the output of the voltage monitoring device 512 allowing to detect a new electron event.

In practice, the voltage across the diode 500 in between two subsequent resets may change over time even in case of no electron event. This change may be caused by the abovementioned dark current in the diode 500 and/or interaction with the voltage monitoring device 512. The amount of interaction with the voltage monitoring device 512 depends amongst others on the impedance of the voltage monitoring device 512, in this case determined by the impedance of the comparator 512a. Another relevant factor may be the time period between two subsequent resets, i.e. a reset frequency.

Hence, the detector may be configured such that (a sum of) voltage changes caused by other circumstances than an electron event do(es) not result in triggering of the comparator 512a. This may be obtained in one or more of the following ways (non-limiting list):
providing a sufficiently large impedance of the voltage monitoring device;
setting a sufficiently high reset frequency; and
setting a sufficiently low reference voltage Vref.

A voltage drop of voltage V2-V0 caused by an electron event is amongst others dependent on the number of generated electron-hole pairs and a capacitance of the diode 500. The higher the number of generated electron-hole pairs, the larger the voltage drop and the smaller the capacitance of the diode 500, the larger the voltage drop. Depending on the type of electron events to be detected by the detector, the voltage drop needs to be sufficiently large to trigger the comparator 512a.

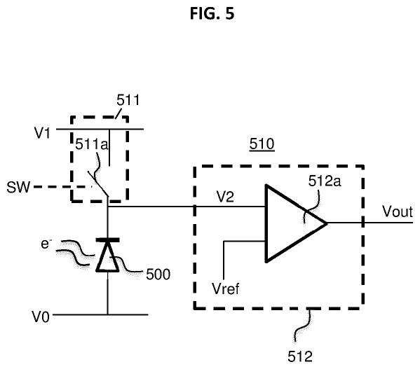

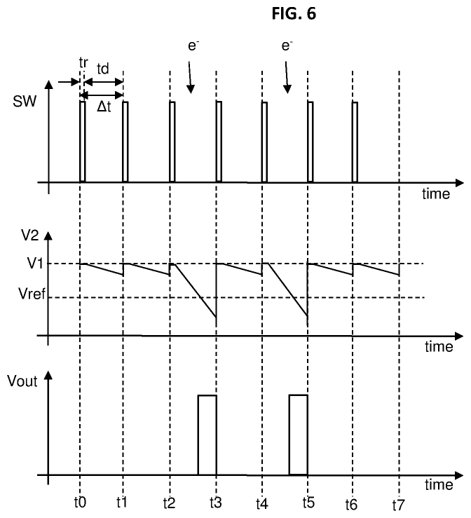

FIG. 6 depicts examples of signal diagrams of a driving signal SW provided to switch 511a of the reset device 511 of FIG. 5 (upper diagram), a voltage V2 (middle diagram), and an output voltage Vout (lower diagram) for five situations in which no electron event occurs and two situations in which an electron event occurs.

The reset device 511 of the detector of FIG. 5 may include or receive a drive signal SW for the switch 511a. As can be seen in the exemplary upper diagram, the drive signal SW is a pulse train of reset pulses at a frequency of 1/Δt with Δt being a duration of one complete reset and detection sequence, i.e. a time interval between time instance to and tn+1, for n being an integer value. The diagrams depict the time instance t0 to t7. Although the reset frequency may be fixed and thus Δt may be constant, it is also possible that Δt and thus the reset frequency is varied or regularly adjusted. At may for instance be 1 ns or smaller resulting in a reset frequency of 1 GHz or higher. Other values of Δt are also envisaged, e.g. smaller than lys (higher than 1 MHz), smaller than 100 ns (higher than 10 MHz), smaller than 10 ns (higher than 100 MHz) or smaller than 100 ps (higher than 10 GHz).

The middle diagram depicts the voltage V2 across the diode 500. When the switch 511a is closed by a pulse in the drive signal SW, the voltage V2 is set to a value V1 due to connecting the cathode side of the diode 500 to voltage V1. As long as the switch 511a is closed, the voltage V2 is maintained at voltage V1 even when an electron event occurs or current leaks from or to the voltage monitoring device. Hence, for a reset period tr, the detector is unable to detect an electron event. This period may alternatively be referred to as dead time. The reset period tr is thus preferably as small as possible, e.g. at most 10% of Δt, at most 1% of Δt or at most 0.1% of Δt. When the drive signal SW is low, and thus the switch 511a is open, the diode 500 in the embodiment of FIG. 5 is reverse biased and operated in open-circuit mode. An electron event is then able to cause a voltage drop in the voltage V2 that may trigger the comparator 512a. Hence, during this detection period td (alternatively referred to as the period in between two subsequent resets), the detector is able to detect an electron event using the voltage monitoring device 512. Please note that Δt=tr+td. It is also possible to compare tr to td, resulting for instance in tr being at most 10% of td, at most 1% of td or at most 0.1% of td.

In the example of FIG. 6, an electron of sufficient energy is incident to the sensing element only in between time instances t2 and t3 and in between time instances t5 and t6. As a result thereof, one or more electron-hole pairs are generated resulting in a voltage drop of voltage V2 to below Vref as can be seen in the middle diagram. This triggers the comparator 512a to change its output Vout from a low level to a high level as indicated in the lower diagram. The high level of Vout is maintained till the next reset and then Vout returns to a low level. It is to be noted that the output Vout may also behave differently, e.g. being high for no electron event and low in case of an electron event, as long as the presence of an electron event can be indicated. When there is no electron event, the voltage V2 drops as described above due to a dark current in the diode or other leakage currents, but does not trigger the comparator.

In the embodiment of FIG. 5, the diode is reverse biased. The diode may be operated in any of the different reverse bias modes, including the normal reverse bias mode, the linear (or proportional) reverse bias mode or the Geiger reverse bias mode. In the normal reverse bias mode, the generated charge resulting in a voltage drop across the diode is substantially equal (gain of 1) to the number of generated electron-hole pairs and may be sufficient for relatively high energy electrons. In the linear (or proportional) reverse bias mode, the electron-hole pairs generated directly upon impact of the electron generate additional electron-hole pairs due to impact ionization thereby resulting in a gain above 1 and thus a larger charge that is responsible for the voltage drop. The linear (or proportional) reverse bias mode is thus suitable for lower energy electrons. For relatively low energy electrons, the Geiger reverse bias mode may be utilized in which the impact ionization effect is stronger and thus gain is even higher.

An advantage of the embodiment of FIG. 5 is that when the diode 500 is operated in Geiger reverse bias mode, the detector can be configured to provide automatic capacitive relaxation quenching when the generated charge is sufficiently large to reduce the reverse bias across the diode 700 thereby relaxing to a non-breakdown regime, e.g. the linear (or proportional) reverse bias mode or even the normal reverse bias mode, and avalanching is automatically quenched.

A further advantage of the embodiment of FIG. 5 is that when the diode 500 is operated in linear (or proportional) reverse bias mode or Geiger reverse bias mode, the avalanching region may be separate from the detector region, so that the avalanching region may be arranged vertically below or above the diode 500. Additionally or alternatively, a backside illumination technology can be used, in which the backside of a substrate is used to receive incident electrons and in which the front side, or alternatively referred to as top side, is used to place circuitry. This allows more electronics to be placed on the top side and increases the ratio of available area for detection compared to the total area, the so-called fill factor. Additionally, a pure Boron technology can be applied to the backside as a passivation treatment. This implantation increases the electron-hole pairs generation as a result of incident electrons by reducing the dead layer region.

Although in the example of FIG. 5, the reset device 511 and the voltage monitoring device 512 are connected to the cathode side of the diode 500, it will be appreciated that the reset device 511 and the diode 500 may be interchanged, i.e. switch place, so that the reset device 511 and the voltage monitoring device 512 are connected to the anode side of the diode 500 and the cathode side of the diode 500 is connected to the voltage V 1. As a result thereof the voltage monitoring device 512 is monitoring a different voltage which may require the use of a different comparator 512a, a different reference voltage Vref and/or the use of additional components to provide the same functioning.

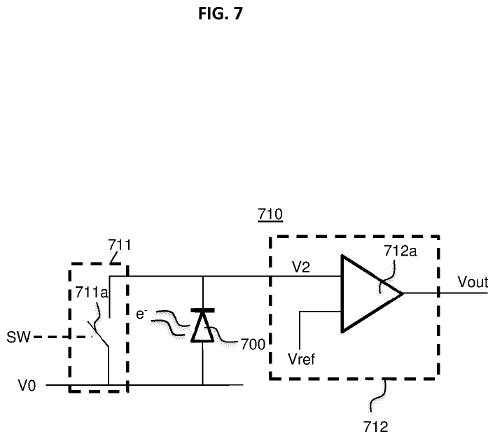

FIG. 7 schematically depicts a diode 700 as part of a sensing element and a circuit 710 configured to detect an electron event caused by an electron impacting the sensing element. The circuit 710 includes a reset device 711 and a voltage monitoring device 712. The anode side and cathode side of the diode 700 are connected to the reset device 711. The cathode side of the diode 700 is also connected to the voltage monitoring device 712.

The reset device 711 is configured to regularly reset the diode 700 by setting a voltage across the diode 700 to a predetermined value, namely 0 Volts, i.e. zero bias. In this embodiment, the reset device 711 includes a switch 711a. When the switch 711a is closed, the cathode side of the diode 700 is connected to V0. As the anode side of the diode 700 is permanently connected to V0, the diode 700 is reset to zero bias upon closing the switch 711a.

In between two subsequent resets, the switch 711a is open thereby operating the diode 700 in open-circuit mode provided that the impedance of the voltage monitoring device 712 is sufficiently high. Electrons incident to the sensing element will create one or more electron-hole pairs. Due to the diode 700 being operated in open-circuit mode, a current is restricted from flowing out of the device resulting in a voltage building up across the diode 700, which voltage can be monitored by the voltage monitoring device 712. In this embodiment, the voltage monitoring device 712 comprises a comparator 712a that compares a voltage V2 at the cathode of the diode 700 with a reference voltage Vref. An output Vout of the comparator then indicates when the voltage V2 is above or below the reference voltage Vref and thus whether an electron event occurred or not. When the voltage build up is large enough to cause the voltage V2 to drop below Vref, the output Vout of the comparator will change thereby indicating the occurrence of at least one electron event. Subsequent resetting of the diode 700 using the reset device 711 will restore the voltage across the diode 700 to 0 Volts level and thus also reset the output of the voltage monitoring device 712 allowing to detect a new electron event.

An advantage of the embodiment of FIG. 7 with the zero bias is that the circuit 710 consumes less power compared to the embodiment of FIG. 5 due to the circuit 710, i.e. the voltage monitoring device 712, being able to operate at low voltage, e.g. below 1V. An advantage of the embodiment of FIG. 5 is that due to the reverse bias the junction's capacitance is decreased resulting in a larger electrical signal caused by the electron event compared to the embodiment of FIG. 7. An advantage of both embodiments is that no transimpedance amplifier or similar electronic device is needed to readout the diode 500 or 700 thereby reducing the required power and thus noise resulting in a better signal-to-noise ratio.

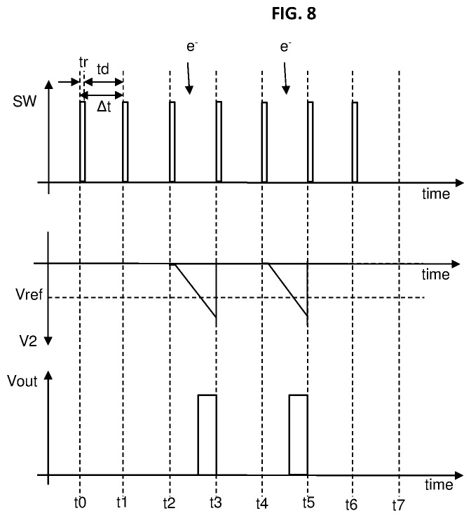

FIG. 8 depicts examples of signal diagrams of a driving signal SW provided to switch 711a of the reset device 711 of FIG. 7 (upper diagram), a voltage V2 (middle diagram), and an output voltage Vout (lower diagram) for five situations in which no electron event occurs and two situations in which an electron event occurs.

The reset device 711 of the detector of FIG. 7 may include or receive a drive signal SW for the switch 711a. As can be seen in the exemplary upper diagram, the drive signal SW is a pulse train of reset pulses at a frequency of 1/At with Δt being a duration of one complete reset and detection sequence, i.e. a time interval between time instance to and tn+1, for n being an integer value. The diagrams depict the time instance t0 to t7. Although the reset frequency may be fixed and thus Δt may be constant, it is also possible that Δt and thus the reset frequency is varied or regularly adjusted. Δt may for instance be 1 ns or smaller resulting in a reset frequency of 1 GHz or higher. Other values of Δt are also envisaged, e.g. smaller than lys (higher than 1 MHz), smaller than 100 ns (higher than 10 MHz), smaller than 10 ns (higher than 100 MHz) or smaller than 100 ps (higher than 10 GHz)

The middle diagram depicts the voltage V2 across the diode 700. When the switch 711a is closed by a pulse in the drive signal SW, the voltage V2 is set to a value V0 due to connecting the cathode side of the diode 500 to voltage V0. As long as the switch 711a is closed, the voltage V2 is maintained at voltage V0 even when an electron event occurs or current leaks from or to the voltage monitoring device. Hence, for a reset period tr, the detector is unable to detect an electron event. This period may alternatively be referred to as dead time. The reset period tr is thus preferably as small as possible, e.g. at most 10% of Δt, at most 1% of Δt or at most 0.1% of Δt. When the drive signal SW is low, and thus the switch 711a is open, the diode 700 in the embodiment of FIG. 5 is operated in open-circuit mode. An electron event is then able to cause a voltage drop in the voltage V2 that may trigger the comparator 712a. Hence, during this detection period td (alternatively referred to as the period in between two subsequent resets), the detector is able to detect an electron event using the voltage monitoring device 712. Please note that Δt=tr+td. It is also possible to compare tr to td, resulting for instance in tr being at most 10% of td, at most 1% of td or at most 0.1% of td.

In the example of FIG. 8, an electron of sufficient energy is incident to the sensing element only in between time instances t2 and t3 and in between time instances t5 and t6. As a result thereof, one or more electron-hole pairs are generated resulting in a voltage drop of voltage V2 to below Vref as can be seen in the middle diagram. This triggers the comparator 712a to change its output Vout from a low level to a high level as indicated in the lower diagram. The high level of Vout is maintained till the next reset and then Vout returns to a low level. It is to be noted that the output Vout may also behave differently, e.g. being high for no electron event and low in case of an electron event, as long as the presence of an electron event can be indicated. When there is no electron event, the voltage V2 is maintained at V0 and thus does not trigger the comparator.

The above examples described in FIGS. 5 and 7 may be used to pixelate a detector as is shown as an example for the detector 144 of FIG. 3G. As an example, shown using dashed lines, the sensor surface 301 is split in three concentric regions AR1, AR2, AR3, each including in this example eight sensing elements denoted by the concentric region followed by a “-” and one of the numbers 1-8. Hence, an annular detector array including 24 detector regions is formed that may be suitable for e.g. a MEMS-based miniature SEM array as will be explained below in more detail.

A MEMS-based miniature SEM array is in principle an array of a plurality of miniature SEMs, wherein miniature refers to the size of each element in the array compared to a conventional SEM. For a conventional SEM, the detector 144 of FIG. 3G may be several millimeters in diameter. However, in MEMS-based miniature SEM, the detector may have a diameter typically smaller than 1 mm, and even smaller than 100 micrometer. FIG. 12 schematically depicts an array 1200 of detectors 144 as can be used in MEMS-based miniature SEM.

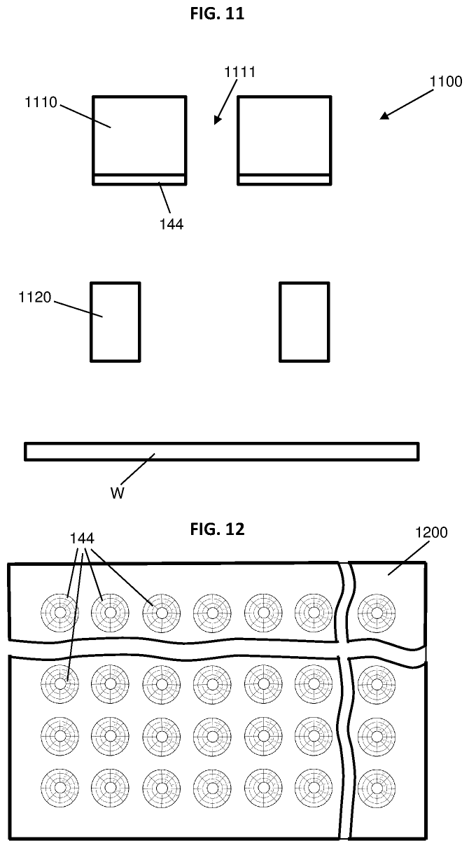

FIG. 11 schematically depicts an element 1100 of a MEMS-based miniature array including two annular electrodes 1110 and 1120. A voltage may be applied between the two annular electrodes 1110 and 1120 and between the lower annular electrode 1120 and a substrate W to be examined using the miniature SEM. The electrodes 1110 and 1120 and the voltages applied between them are configured to direct an electron beam coming through a hole 1111 in electrode 1110 towards the substrate W and to direct backscattered or secondary electrons from the substrate W to a detector 144 arranged at a bottom of the electrode 1110. The detector 144 has in this embodiment a structure as explained by reference to FIG. 3G.

Due to the relatively small size of the components, e.g. electrodes and other non-shown components like deflectors, the alignment between the various components in the miniature SEM array must be very accurate. Only extremely tight tolerances may be allowed. As a result thereof, temperature variations in the array need to be minimized.

Prior art detectors, such as a Faraday cup, may have the disadvantage that internal electron gain is relatively low, typically about 1, thereby limiting the pixel rate and thus throughput significantly. Prior art detectors having sufficient internal electron gain to overcome this disadvantage have the disadvantage that the power consumption is relatively high resulting in relatively high temperature gradients within the array.

By using sensing elements including a circuit according to the invention, e.g. as depicted in FIG. 5 or 7, the power consumption of the detector 144 is significantly reduced. However, alternatively or additionally, a reduction in power consumption can be obtained by minimizing the number of sensing elements and thus minimizing the number of circuits.

An important parameter of a detector is the miscount rate defined as the average number of electrons that are not counted compared to the total number of electrons that were incident to the detector. The miscount rate can be calculated by the formulae: dead time of the detector divided by average time between successive electrons arriving at the detector. Preferably, the miscount rate is <5% to have sufficient gain linearity for electron beam substrate inspection without statistical correction.

Assuming that in a practical example, a primary beam current is 100 pA with a maximum yield of 2.5 at a pattern edge on a sample, so that a maximum current caused by secondary electrons/backscattered electrons is 250 pA, that 30% of that maximum current is undetected as it not incident on the detector, 40% is incident on the first concentric region AR1, 20% is incident on the second concentric region AR2, and 10% is incident on the third concentric region AR, and that the dead time of a sensing element of the detector 144 according to the invention can easily be as low as 600 ps, then the miscount rate can be calculated as follows.

Concentric region AR1 receives 40%*250 pA=100 pA, leading to 100 pA/8 detectors=12.5 pA current per sensing element AR1-1 to AR1-8. Each sensing element thus receives about 0.078 electrons per nanosecond considering that 1 A=1 C/s with C=6.241509074*10¹⁸ electrons. Hence, on average, for each sensing element, an electron arrives every 12.8 ns, resulting to a miscount rate of 0.6 ns/12.8 ns=4.7%. Similar calculations lead to miscount rates of 2.3% for the second concentric region AR2 and 1.2% for the third concentric region AR3. The overall miscount rate of the entire detector 144 can then be estimated to be (4.7%*40%+2.4%*20%+1.2%*10%)/(70%)=3.5%.

When the sensing elements of FIG. 3G are connected to a circuit as depicted in FIG. 5 or 7, the output of the circuit is a stream of pulses for every detected electron. The pulses can be counted using a counter, e.g. an asynchronous counter. In case of a pixel refresh rate of 10 MHz or higher, the maximum number of electrons to be counted is about 7.8 electrons (0.078 electrons/ns*100 ns) and thus a 4 bits asynchronous counter suffices with a minimal risk of overflow of the counter. All counters can be connected to a summing device configured to sum up all counters.

An advantage of applying the detectors according to the invention in a MEMS-based SEM array is that power consumption is low, resulting in a low thermal load with less temperature variations. Another advantage may be the low signal-to-noise ratio and/or the small circuit layout area. Further, as the diode in the sensing element may have a relatively large internal electron gain, applications in which the number of electrons per pixel should be limited, e.g. to prevent a developed resist pattern on the substrate W from being destroyed or damaged, become feasible with a detector according to the invention. It may further be possible to increase the pixel rate.

FIG. 9 depicts a schematic of a normal diode architecture 311C that can be used as a sensing element in accordance with the invention. The architecture includes a p-type layer 110 on which is formed a heavily doped n-type layer 130. The p-type and n-type layers may have a particular doping concentration, which may be constant or vary within that particular layer or region. On top of the n-type layer is provided an epitaxial region 171 of either p- or n-type. The epitaxial region 171 may be of low or high resistivity depending on the design of the diode architecture. Within the epitaxy region 171 an n-type layer 170 is formed as shown. Optionally, within the epitaxy region 171, a deep trench isolation region 165 may be formed to isolate different pixels and circuitry from one another. The deep trench isolation region 165 may extend all the way to the n-type layer 130. The deep trench isolation region 165 may be separated from the n-type region 130. It is possible to size the n-type region 130 by offsetting from the edges of the device in all directions.

A connection 210 is made to the n-type layer 170 at a front side of the device. A further connection 220 is made at a backside of the substrate providing a connection to the p-type layer 110. The p-type layer 110 may be formed using a pure Boron technology as a passivation treatment.

The epitaxy region 171 is fully or over depleted and may be of the high-resistivity type. The potential thus created in the epitaxy region not only fully depletes the epitaxy region, but also reverse biases the heavily doped n-type layer 130. The thickness and doping concentrations of the n-type layer 130 and the p-type layer 110 are chosen such that it reverse biases the backside and generates a very high electric field zone 230. This allows to detect electrons at the backside of the device thereby increasing the fill factor when all circuitry is placed on the front side.

When an incoming electron is received in the high electric field zone 230, excess electrons are generated thereby triggering an avalanche. The generated electrons then travel to the highest potential at the front side and are collected by the diode formed by the epitaxy region 171 and the n-type layer 170. This leads to the discharge of the diode that can be detected with the circuitry as described in relation to FIGS. 5 to 8.

Hence, with the embodiment of FIG. 9, the high-electric field zone used for the avalanche effect is arranged at another location then the diode structure.

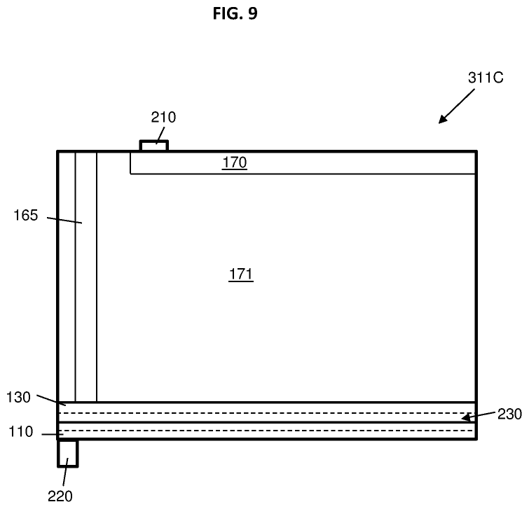

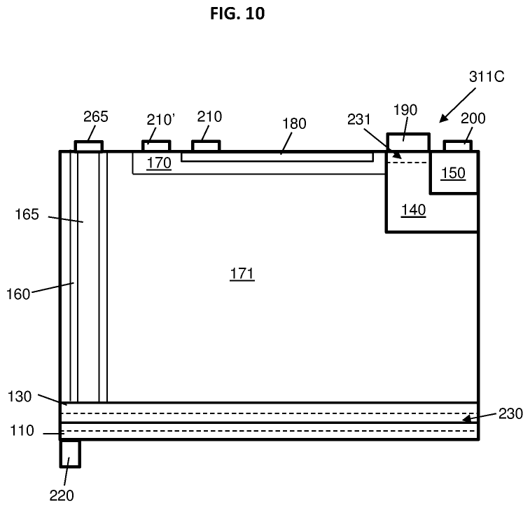

FIG. 10 depicts a schematic of a pinned or partially pinned diode architecture 311D that can be used as a sensing element in accordance with the invention. The architecture includes a p-type layer 110 on which is formed a heavily doped n-type layer 130. The p-type and n-type layers may have a particular doping concentration, which may be constant or vary within that particular layer or region. On top of the n-type layer is provided an epitaxial region 171 of either p- or n-type, in this case p-type. The epitaxy region 171 may be of low or high resistivity depending on the design of the diode architecture. Within the epitaxy region 171 an n-type layer 170 is formed as shown, and a p-type implant or well 140 with an n-type layer or region 150. Region 140 may also serve as a p-type well for other pixel circuitry (not shown). The p-type implant or well 140 and the n-type layer or region 150 together form a transistor area.

Optionally, within the epitaxy region 171, a deep trench isolation region 165 with a passivation layer 160 may be formed to isolate different pixels and circuitry from one another. The deep trench isolation region 165 may extend all the way to the n-type layer 130.

A connection 210 is made to the p-type layer 180 at a front side of the device. When the n-type layer 170 is offset to the left relative to the p-type layer 180, a contact 210′ may be provided to additionally reverse bias the diode. When the n-type layer 170 is offset to the right relative to the p-type layer 180, it is a fully pinned diode. A further connection 220 is made at a backside of the substrate providing a connection to the p-type layer 110. The p-type layer 110 and/or the p-type layer 180 may be formed using a pure Boron technology as a passivation treatment.

The epitaxy region 171 is fully or over depleted and may be of the high-resistivity type. The potential thus created in the epitaxy region not only fully depletes the epitaxy region, but also reverse biases the heavily doped n-type layer 130. The thickness and doping concentrations of the n-type layer 130 and the p-type layer 110 may be chosen such that it reverse biases the backside and generates a very high electric field zone 230. This allows to detect electrons at the backside of the device thereby increasing the fill factor when all circuitry is placed on the front side.

When an incoming electron is received in the high electric field zone 230, excess electrons are generated thereby triggering an avalanche. The generated electrons then discharge the diode.

In effect, as shown in FIG. 10, each layer of the p-n-p structure of the pinned diode 311D may have a different bias. The top p-type layer 180 is biased to the reference potential or voltage and may be connected to the p-type well 140 of the transistor area. The bottom p-type layer defined by the p-type layer 171 and/or the p-type layer 110 may be biased at a negative voltage. The middle n-type layer 170 is internally biased. The bias cannot exceed the so-called “pinning voltage” as it is reached when all electrons are extracted from the n-type layer via a transfer gate 190 connecting the n-type layer 150 with the n-type layer 170. The doping concentrations and thickness of the layer 140 can be used to generate a high electric field zone 231 underneath the transfer gate 190. Alternatively, the high electric field zone may be generated between the layers 170 and 180.

The passivation layer 160 around the deep trench isolation 165 may aid in reducing dark current. Further, the deep trench isolation 165 may be provided with a contact 265 to offer more flexibility in biasing and operation control.

A floating diffusion connection 200 is provided on the n-type layer or region 150 within the p-type well 140.

Although in the above descriptions relating to FIGS. 9 and 10, specific doping types have been mentioned, but it will be appreciated by the skilled person that doping types may be changed to make it either an electron dominant device or a hole dominant device.

In some embodiments, a detector may communicate with a controller that controls a charged particle beam system. The controller may instruct components of the charged particle beam system to perform various functions, such as controlling a charged particle source to generate a charged particle beam and controlling a deflector to scan the charged particle beam. The controller may also perform various other functions such as adjusting a sampling rate of a detector, resetting sensing element, or performing image processing. The controller may comprise a storage that is a storage medium such as a hard disk, random access memory (RAM), other types of computer readable memory, and the like. The storage may be used for saving scanned raw image data as original images, and post-processed images. A non-transitory computer readable medium may be provided that stores instructions for a processor of controller 109 to carry out charged particle beam detection, sampling period determination, image processing, or other functions and methods consistent with the present disclosure. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a ROM, a PROM, and EPROM, a FLASH-EPROM or any other flash memory, NVRAM, a cache, a register, any other memory chip or cartridge, and networked versions of the same.

Block diagrams in the figures may illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions. The embodiments may further be described using the following clauses:
1. A detector for a charged particle apparatus comprising:
   a sensing element including a diode; and
   a circuit configured to detect an electron event caused by an electron impacting the sensing element,
   wherein the circuit comprises a voltage monitoring device and a reset device,
   wherein the reset device is configured to regularly reset the diode by setting a voltage across the diode to a predetermined value, and
   wherein the voltage monitoring device is connected to the diode to monitor a voltage across the diode in between resets.
2. The detector according to clause 1, wherein the reset device is configured to set a voltage across the diode such that the diode is reverse biased.
3. The detector according to clause 2, wherein the diode is reverse biased during reset such that the diode is operated in a no-gain mode.
4. The detector according to clause 2, wherein the diode is reverse biased during reset such that the diode is operated in a linear region.
5. The detector according to clause 2, wherein the diode is reverse biased during reset such that the diode is operated in a Geiger mode.
6. The detector according to clause 1, wherein the reset device is configured to set the voltage across the diode to zero.
7. The detector according to clause 1, wherein the reset device is configured to reset the diode at a frequency of at least 1 MHz, preferably at least 10 MHz, more preferably at least 100 MHz and most preferably at least 1 GHz.
8. The detector according to clause 1, wherein the reset device is configured to reset the diode in a reset period that is at most 10% of the time period in between resets, preferably at most 1% of the time period in between resets, and more preferably at most 0.1% of the time period in between resets.
9. The detector according to clause 1, wherein the reset device includes a switch connecting the diode to a voltage of a predetermined value when closed to reset the diode.
10. The detector according to clause 1, wherein the voltage monitoring device includes a discriminator to determine when a voltage change of the voltage across the diode exceeds a predetermined value.
11. The detector according to clause 10, wherein the voltage monitoring device has an impedance such that a voltage change across the diode caused by the voltage monitoring device itself in between resets is less than 50% of the predetermined value, preferably less than 20% of the predetermined value, more preferably less than 10% of the predetermined value.
12. The detector of clause 1, wherein the diode is a PIN diode or an avalanche diode.
13. The detector of clause 1, wherein the capacitance of the diode is below a predetermined value.
14. The detector of clause 1, including a plurality of sensing elements and corresponding circuits configured to detect an electron event caused by an electron impacting the corresponding sensing element, each sensing element including a corresponding diode, and each circuit comprising a corresponding voltage monitoring device and a corresponding reset device, wherein each reset device is configured to regularly reset the corresponding diode by setting a voltage across the corresponding diode to a predetermined value, and each voltage monitoring device is connected to the corresponding diode to monitor a voltage across the corresponding diode in between resets.
15. The detector of clause 1, wherein the circuit is configured to count electron events caused by an electron impacting the sensing element.
16. The detector of clause 15, wherein the circuit comprises a device to store the count.
17. The detector of clause 14, wherein each circuit is configured to count electron events caused by an electron impacting the sensing element and comprises a device to store the count, and wherein the detector includes a summing circuit configured to sum the electron event counts of the circuits of the sensing elements.
18. The detector of clause 1 formed in a substrate, wherein the diode and at least a part of the circuit are arranged at a front side of the substrate, and wherein the sensing element comprises a sensing area connected to the diode and arranged at a backside of the substrate opposite the front side to receive electrons causing an electron event.
19. The detector of clause 18, wherein an avalanche region is provided at the sensing area.
20. The detector of clause 18, wherein an avalanche region is provided between the diode and the circuit, wherein preferably the circuit includes a transfer gate and the avalanche region is arranged underneath the transfer gate.
21. A method comprising:
   regularly resetting a diode of a sensing element by setting a voltage across the diode to a predetermined value;
   monitoring a voltage across the diode in between resets, wherein the diode is operated in open-circuit mode.
22. A method according to clause 15, wherein the voltage across the diode set during a reset is such that the diode is reverse biased.
23. A detector array for a charged particle apparatus comprising a plurality of detectors according to clause 1.
24. A detector array according to clause 23, wherein the charged particle apparatus is a MEMS-based miniature SEM array.
25. A detector array for a charged particle apparatus with multiple beamlets, comprising a plurality of detectors, wherein each of the detectors is associated with a different beamlet and comprises:
   a plurality of sensing elements, wherein each sensing element includes a diode;
   a plurality of circuits; and
   a summing circuit,
   wherein each of the circuits corresponds to a sensing element and is configured to detect and count an electron event caused by an electron impacting the corresponding sensing element,
   wherein each of the circuits comprises a voltage monitoring device, a reset device, and a device to store the count,
   and wherein the summing circuit is configured to sum the electron event counts of the circuits of the corresponding detector.
26. A detector array according to clause 25, wherein each reset device is configured to regularly reset the corresponding diode by setting a voltage across the diode to a predetermined value, and wherein each voltage monitoring device is configured to monitor a voltage across the diode in between resets.
27. A detector array according to clause 26, wherein the diode is operated in open-circuit mode in between resets.
28. A diode architecture including:
   a substrate;
   a sensing element including a diode formed in or on the substrate; and
   at least a part of a circuit formed in or on the substrate and configured to detect an electron event caused by an electron impacting the sensing element,
   wherein an avalanche region is provided between the diode and the circuit.
29. A diode architecture according to clause 28, wherein the circuit includes a transfer gate, and wherein the avalanche region is arranged underneath the transfer gate.
30. A diode architecture according to clause 28, wherein the diode and the circuit are arranged at a front side of the substrate, and wherein the sensing element comprises a sensing area connected to the diode and arranged at a backside of the substrate opposite the front side to receive electrons causing an electron event.
31. A diode architecture including:
   a substrate;
   a sensing element including a diode formed in or on the substrate; and
   at least a part of a circuit formed in or on the substrate and configured to detect an electron event caused by an electron impacting the sensing element,
   wherein the diode and the circuit are arranged at a front side of the substrate,
   wherein the sensing element comprises a sensing area connected to the diode and arranged at a backside of the substrate opposite the front side to receive electrons causing an electron event, and
   wherein an avalanche region is provided at the sensing area.

It will be appreciated that the present invention is not limited to the exact construction that has been described above and illustrated in the accompanying drawings, and that various modifications and changes can be made without departing from the scope thereof. For example, while a PIN diode has been discussed with reference to certain exemplary embodiments, other types of diodes, such as a NIP diode may be similarly applied. Furthermore, other types of devices that may generate a measurable signal in response to receiving incident energy may be applied in a detector.

It will be understood that elements shown in separate figures may be combined.

Furthermore, while scanning electron microscopy has been discussed with reference to some embodiments, other types of systems may be applicable as well. For example, a detector may be used in transmission electron microscopy (TEM), scanning transmission electron microscopy (STEM), or structured illumination microscopy (SIM) systems.

1. A detector for a charged particle apparatus comprising:
a sensing element including a diode; and
a circuit configured to detect an electron event caused by an electron impacting the sensing element,
wherein the circuit comprises a voltage monitoring device and a reset device,
wherein the reset device is configured to regularly reset the diode by setting a voltage across the diode to a predetermined value,
and wherein the voltage monitoring device is connected to the diode to monitor a voltage across the diode in between resets.

2. The detector according to claim 1, wherein the reset device is configured to set a voltage across the diode such that the diode is reverse biased.

3. The detector according to claim 2, wherein the diode is reverse biased during reset such that the diode is operated in a no-gain mode.

4. The detector according to claim 2, wherein the diode is reverse biased during reset such that the diode is operated in a linear region.

5. The detector according to claim 2, wherein the diode is reverse biased during reset such that the diode is operated in a Geiger mode.

6. The detector according to claim 1, wherein the reset device is configured to set the voltage across the diode to zero.

7. The detector according to claim 1, wherein the reset device is configured to reset the diode at a frequency of at least 1 MHz, preferably at least 10 MHz, more preferably at least 100 MHz and most preferably at least 1 GHz.

8. The detector according to claim 1, wherein the reset device is configured to reset the diode in a reset period that is at most 10% of the time period in between resets, preferably at most 1% of the time period in between resets, and more preferably at most 0.1% of the time period in between resets.

9. The detector according to claim 1, wherein the reset device includes a switch connecting the diode to a voltage of a predetermined value when closed to reset the diode.

10. The detector according to claim 1, wherein the voltage monitoring device includes a discriminator to determine when a voltage change of the voltage across the diode exceeds a predetermined value.

11. The detector according to claim 10, wherein the voltage monitoring device has an impedance such that a voltage change across the diode caused by the voltage monitoring device itself in between resets is less than 50% of the predetermined value, preferably less than 20% of the predetermined value, more preferably less than 10% of the predetermined value.

12. The detector of claim 1, wherein the diode is a PIN diode or an avalanche diode.

13. The detector of claim 1, wherein the capacitance of the diode is below a predetermined value.

14. The detector of claim 1, including a plurality of sensing elements and corresponding circuits configured to detect an electron event caused by an electron impacting the corresponding sensing element, each sensing element including a corresponding diode, and each circuit comprising a corresponding voltage monitoring device and a corresponding reset device, wherein each reset device is configured to regularly reset the corresponding diode by setting a voltage across the corresponding diode to a predetermined value, and each voltage monitoring device is connected to the corresponding diode to monitor a voltage across the corresponding diode in between resets.

15. The detector of claim 1, wherein the circuit is configured to count electron events caused by an electron impacting the sensing element.

16. A detector array for a charged particle apparatus with multiple beamlets, comprising a plurality of detectors, wherein each of the detectors is associated with a different beamlet and comprises:
a plurality of sensing elements, wherein each sensing element includes a diode;
a plurality of circuits; and
a summing circuit,
wherein each of the circuits corresponds to a sensing element and is configured to detect and count an electron event caused by an electron impacting the corresponding sensing element,
wherein each of the circuits comprises a voltage monitoring device, a reset device, and a device to store the count,
and wherein the summing circuit is configured to sum the electron event counts of the circuits of the corresponding detector.

17. The detector array according to claim 16, wherein each reset device is configured to regularly reset the corresponding diode by setting a voltage across the diode to a predetermined value, and wherein each voltage monitoring device is configured to monitor a voltage across the diode in between resets.

18. The detector array according to claim 17, wherein the diode is operated in open-circuit mode in between resets.

19. A diode architecture comprising:
a substrate;
a sensing element including a diode formed in or on the substrate; and
at least a part of a circuit formed in or on the substrate and configured to detect an electron event caused by an electron impacting the sensing element,
wherein an avalanche region is provided between the diode and the circuit.

20. The diode architecture according to claim 19, wherein the circuit includes a transfer gate, and wherein the avalanche region is arranged underneath the transfer gate.
